(19) United States
(12) Patent Application Publication
(10) Pub. No.: US 2025/0248089 A1
(43) Pub. Date: Jul. 31, 2025

(54) 3D MICRO-CURVED EPITAXIAL STRUCTURE AND PREPARATION METHOD

(71) Applicant: SUZHOU HAN HUA SEMICONDUCTOR CO., LTD., Suzhou (CN)

(72) Inventors: Xianfeng Ni, Suzhou (CN); Qian Fan, Suzhou (CN)

(73) Assignee: SUZHOU HAN HUA SEMICONDUCTOR CO., LTD., Suzhou (CN)

(21) Appl. No.: 18/901,368

(22) Filed: Sep. 30, 2024

(30) Foreign Application Priority Data
Jan. 26, 2024 (CN) 202410108333X

(51) Int. Cl. H01L 29/15; C30B 25/04; C30B 25/18; C30B 29/38; G03F 7/00; G03F 7/20; G03F 7/24; H01L 21/02; H01L 21/467

(52) U.S. Cl. CPC H10D 62/8161; C30B 25/04; C30B 25/186; C30B 29/38; G03F 7/2002; G03F 7/24; G03F 7/70025; H01L 21/0262; H01L 21/467

(57) ABSTRACT

A 3D micro-curved epitaxial functional structure comprises a base layer that includes, from bottom to top, at least a sapphire substrate layer and a first epitaxial layer. A mask layer is located above the base layer, with spaced grooves that extend through it and expose the upper surface of the base layer. Multiple 3D micro-curved epitaxial structural units are formed, each with its bottom part filling a corresponding groove and its upper surface exhibiting a smooth 3D curved structure. Each 3D micro-curved epitaxial structural unit is partially in contact with the upper surface of the mask layer. By introducing an excess of Ga source while adjusting the crystal plane orientation angle during wet etching with Sc source, multiple epitaxial growth processes are performed to form the 3D micro-curved epitaxial functional structure, achieving compatibility with chip epitaxial processes and providing technical feasibility for creating complex structures.

### CROSS-REFERENCE TO RELATED APPLICATIONS

This application claims benefit of the filing date of Chinese Patent Application No. 202410108333.X filed on Jan. 26, 2024, the disclosure of which is hereby incorporated in its entirety by reference.

### TECHNICAL FIELD OF THE INVENTION

The present invention relates to the field of semiconductor epitaxial technology, and more specifically to a three-dimensional (3D) micro-curved epitaxial structure with self-adaptive crystal plane and crystal orientation growth and its preparation method.

### BACKGROUND OF THE INVENTION

As technology continues to advance, the demand for novel devices is also increasing. Complex chip devices often have numerous structural and functional layers, requiring further material growth after the initial chip fabrication to synthesize additional functional layers. This process typically involves Metal-organic Chemical Vapor Deposition (MOCVD) high-temperature (greater than 1000° C.) epitaxial growth, followed by growth of the chip structural layer in a low-temperature (less than 900° C.) environment. This cycle may repeat, involving multiple epitaxial synthesis processes. However, due to the presence of passivation layers and metal layers in the initial epitaxial structure that are not heat-resistant, using the MOCVD high-temperature epitaxial process after the chip structure is grown can damage the entire chip structure, posing issues of multiple epitaxial compatibility.

Furthermore, the majority of existing chip device structures incorporate a layered thin-film epitaxial structure. Despite attempts to modify the three-dimensional shape of the crystal layer through selective growth, the light emitted from the quantum well layer still exhibits a refraction angle, leading to a decrease in light extraction efficiency. As a result, there are considerable constraints in designing complex 3D composite micro-curved structures and subsequent intricate chip architectures, effectively limiting the ability to design complex device structures that require multiple epitaxial layers.

### SUMMARY OF THE INVENTION

The present disclosure provides a 3D micro-curved epitaxial functional structure that can self-adjust the crystal plane and crystal direction growth, along with its preparation method. This aims to address the compatibility problem between the chip process and the epitaxial process when preparing complex chip devices, and to grow complex 3D micro-curved epitaxial structures. In order to solve the above technical problems, the present disclosure provides a method for preparing a 3D micro-curved epitaxial structure with self-adaptive crystal plane and crystal orientation growth, comprising:
S1. providing a base layer, which includes at least a sapphire substrate layer and a first epitaxial layer in order from bottom to top;
S2. growing a mask layer above the base layer;
S3. dry etching the mask layer to form spaced grooves, wherein the grooves penetrate through the mask layer and have their bottoms positioned on the upper surface of the base layer;
S4. placing the 3D micro-curved epitaxial structure into an MOCVD reactor, and introducing hydrogen (H₂), ammonia (NH₃), and nitrogen (N₂), a scandium (Sc) source, and an excess gallium (Ga) source under a temperature range of 400˜900° C. to grow 3D micro-curved epitaxial structural units;
S5. performing photolithography on the 3D micro-curved epitaxial structural unit to define the area to be etched;
S6. wet etching the area to be etched to form a structure comprising one polar plane F3 and two semi-polar planes F1;
S7. repeating S4 to S6 until the 3D micro-curved epitaxial structural unit with a smooth upper surface is formed.

In a specific embodiment, the Ga source flow rate is 10,000 sccm to 100,000 sccm, the H₂ flow rate is 50 L/min to 100 L/min, the NH₃ flow rate is 50 L/min to 100 L/min, and the N₂ flow rate is 50 L/min to 150 L/min. Ga sources include trimethylgallium (TMG) and triethylgallium (TEG), and Sc sources include trimethylscandium (TMS) and triethylscandium (TESc).

In a specific embodiment, it also includes introducing an aluminum (Al) source, the flow rate of the Al source is 50 sccm to 1000 sccm, and the molar molecular weight ratio of the Al source component is 5% to 90%.

In a specific embodiment, the number of repeated execution times of the step S7 is 3 to 10.

In a specific embodiment, an additional functional layer is grown on the outer surface of the 3D micro-curved epitaxial structural unit, and the additional functional layer and the 3D micro-curved epitaxial structural unit form a heterojunction superlattice multi-quantum well structural layer or channel layer.

In a specific embodiment, the molar molecular weight ratio of the Sc source component is 5% to 30%.

Based on the same inventive concept, the present invention also provides a 3D micro-curved epitaxial structure that can self-adaptive crystal plane and crystal orientation growth, comprising:
a base layer, which includes at least a sapphire substrate layer and a first epitaxial layer, arranged sequentially from bottom to top;
a mask layer is located above the base layer;
the mask layer is provided with grooves distributed at intervals, and the grooves penetrate the mask layer and expose the upper surface of the base layer;
a plurality of 3D micro-curved epitaxial structural units, the bottom part of each of the 3D micro-curved epitaxial structural units is filled with the corresponding groove, and the upper surface is a smooth 3D micro-curved structure, and each 3D micro-curved epitaxial structure unit is in contact with the upper surface of the mask layer.

In a specific embodiment, the material of the mask layer being AlN or SiN, and the material of the 3D micro-curved epitaxial structural units being scandium gallium nitride (ScGaN) or scandium aluminum gallium nitride (ScAlGaN) and its superlattice structure.

In a specific embodiment, it further comprises an additional functional layer that covers the 3D micro-curved epitaxial structural unit and forms a heterojunction superlattice multi-quantum well structure or channel layer with the 3D micro-curved epitaxial structural unit.

In a specific embodiment, the vertical height of the 3D micro-curved epitaxial structural unit from the bottom of the groove to the top of the upper surface is 1 μm to 7 μm.

In a specific embodiment, the curvature of the 3D micro-curved epitaxial structural unit is 1000R to 1800R.

Compared with the prior art, the present invention proposes a 3D micro-curved epitaxial functional structure that can self-adjust the growth of crystal planes and directions. Its beneficial effects at least include:
1. MOCVD grows 3D micro-curved epitaxial structural units, with an excess of Ga source acting as a surfactant or surface lubricant, binding to the semi-polar surface to achieve selective growth of ScGaN film. Simultaneously, the crystal orientation angle of the crystal plane during wet etching is modulated by adjusting the Sc source composition. Through multiple cycles of epitaxial growth, the upper surface is ensured to remain sufficiently smooth, thereby enhancing the quality of the curved structures.
2. After the chip is grown, continuous epitaxial growth of required structures can be performed on the chip, achieving compatibility between chip processing and epitaxial processing, thereby providing technical feasibility for the realization of complex structures.
3. The 3D micro-curved epitaxial structural units are grown at a low temperature range of 400 to 900° C., utilizing ScGaN and its superlattice configuration, which offer superior lattice and thermal matching. This approach overcomes the limitations of traditional methods, where high-temperature intolerance of passivation and metal layers hindered repeated epitaxial growth.

Beneficial effects further include:
1. The ScGaN/ScAlGaN alloy layer is inherently resistant to strong acid etching. Its etching resistance can be tailored by adjusting its composition. This makes it an excellent etch-stopping layer material for wet etching during epitaxy in vertical structures. Coupled with the introduction of an excess Ga source, it enables multiple epitaxial growths into a 3D micro-curved epitaxial functional structure with a smooth surface. This material is particularly suitable for the fabrication of high-frequency, high-power GaN vertical high-electron-mobility transistor (HEMT) devices that incorporate 3D micro-curved structures.
2. Structural modulation allows for the growth of additional functional layers based on specific application requirements. The 3D micro-curved epitaxial structure is ideally suited for Micro LED applications. The heterojunction superlattice multi-quantum well structure layer emits light that is vertically oriented everywhere, virtually reaching 100% of the theoretical light emitting efficiency, thereby significantly enhancing the light extraction efficiency.
3. The resulting 3D micro-curved epitaxial structural units exhibit a small curvature, fully complying with the curvature design specifications demanded by the existing curved screen market.

### BRIEF DESCRIPTION OF THE DRAWINGS

FIG. 1 depicts a structural diagram of a traditional film epitaxial structure;

FIGS. 2 to 10 illustrate structural diagrams of various process steps for preparing a 3D micro-curved epitaxial structure with self-adaptive crystal plane and crystal orientation growth according to embodiments of the present invention;

FIG. 11a is a schematic diagram of the structure after growing additional functional layers for the 3D micro-curved epitaxial structure;

FIG. 11b is a schematic diagram of the overall structure after growing additional functional layers for the 3D micro-curved epitaxial structure;

FIG. 12 illustrates a schematic diagram of the epitaxial structure for Comparative Example 1.

Among them, the reference symbols are explained as follows:

1—base layer, 11—sapphire substrate, 12—first epitaxial layer, 2—mask layer, 3—first photoresist layer, 4—groove, 5—3D micro-curved epitaxial structure unit, 6—second photoresist layer, 7—area to be etched, 8—third photoresist layer, 9—additional functional layer.

### DETAILED DESCRIPTION

The 3D micro-curved epitaxial structure with self-adaptive crystal plane and crystal orientation growth and its preparation method will be further described in detail below with reference to the accompanying drawings and specific embodiments. The advantages and features of the present invention will become clearer from the following description. It should be noted that the drawings are in a very simplified form and use imprecise proportions, and are only used to conveniently and clearly assist in explaining the embodiments of the present invention. In addition, the structures shown in the drawings are often part of the actual structure. In particular, each drawing needs to display different emphasis, and sometimes uses different proportions.

FIG. 1 depicts a structural diagram of a traditional film epitaxial structure. From bottom to top, there are sapphire substrate 11, first epitaxial layer 12, metal layer 13, and passivation layer 14. This structure needs to be used on sapphire substrate 11 when the temperature is greater than 1000° C. The MOCVD process grows the first epitaxial layer 12, and then grows the metal layer 13 and the passivation layer 14. Since both the metal layer 13 and the passivation layer 14 are not resistant to high temperatures, they cannot be subjected to high-temperature epitaxy again. Complex structural layers of chip devices cannot be achieved through multiple epitaxy in a traditional way.

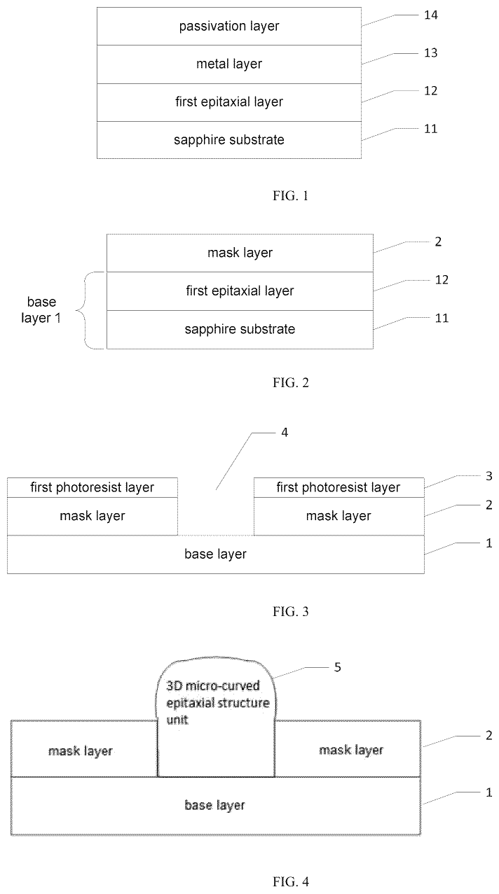

FIGS. 2 to 10 illustrate structural diagrams of various process steps for preparing a 3D micro-curved epitaxial functional structure with self-adaptive crystal plane and crystal orientation growth according to embodiments of the present invention. Referring to FIG. 2, a base layer 1 is provided, and the base layer 1 includes a sapphire substrate 11 and a first epitaxial layer 12. A mask layer 2 is grown. The mask layer 2 covers the base layer 1. The mask layer 2 is made of AIN or SiN and has a thickness of 20 nm to 500 nm. When the material of the mask layer 2 is AlN, it is grown by the Chemical Vapor Deposition (CVD) process, where the reaction temperature is constant, and the value range is usually from 75° C. to 500° C.; When the material of the mask layer 2 is SiN, it is grown by the Physical Vapor Deposition (PVD) or CVD process.

Referring to FIG. 3, coat the first photoresist layer 3 on top of the mask layer 2. Irradiate the first photoresist layer 3 with ultraviolet light or a laser, and then use a developer to remove the exposed portion of the first photoresist layer 3, thus forming a pattern of areas to be etched on the surface of the mask layer 2. The mask layer 2 is then dry-etched using inductively coupled plasma (ICP) to form spaced grooves 4. The grooves 4 penetrate the mask layer 2 and have their bottoms located on the upper surface of the base layer 1. These evenly distributed grooves 4 are more conducive to the full utilization of materials.

Referring to FIG. 4, the 3D micro-curved epitaxial structural unit 5 is grown by placing the 3D micro-curved epitaxial functional structure into an MOCVD reactor and introducing H₂, NH₃, N₂, a Sc source, and an excess Ga source in an environment of 400 to 900° C. The Ga source flow rate is 10,000 sccm to 100,000 sccm, the H₂ flow rate is 50 L/min to 100 L/min, the NH₃ flow rate is 50 L/min to 100 L/min, and the N₂ flow rate is 50 L/min to 150 L/min. As a result, the 3D micro-curved epitaxial structural unit 5 made of ScGaN alloy is grown. Notably, the Ga source flow rate is 10 to 100 times higher than that of the traditional growth method. The excess Ga source is used as a surfactant or surface lubricant to control the growth rate of the semi-polar surface, providing a better environment for the curved surface growth of the 3D micro-curved epitaxial structural unit 5. Additionally, the Al source can also be introduced simultaneously, with a flow rate of 50 sccm to 1000 sccm. By adjusting the molar molecular weight ratio of the Al source components to 5% to 90%, a 3D micro-curved epitaxial structure of ScAlGaN alloy material can be grown. The temperature in the MOCVD reactor is 400 to 900° C., instead of the traditional high temperature above 1000° C., enabling multiple epitaxial growths of 3D micro-curved epitaxial structural units 5 of ScGaN or ScAlGaN alloy layers.

Referring to FIG. 5, the 3D micro-curved epitaxial functional structure is coated with the second photoresist layer 6, exposed, and developed to determine the area 7 to be etched.

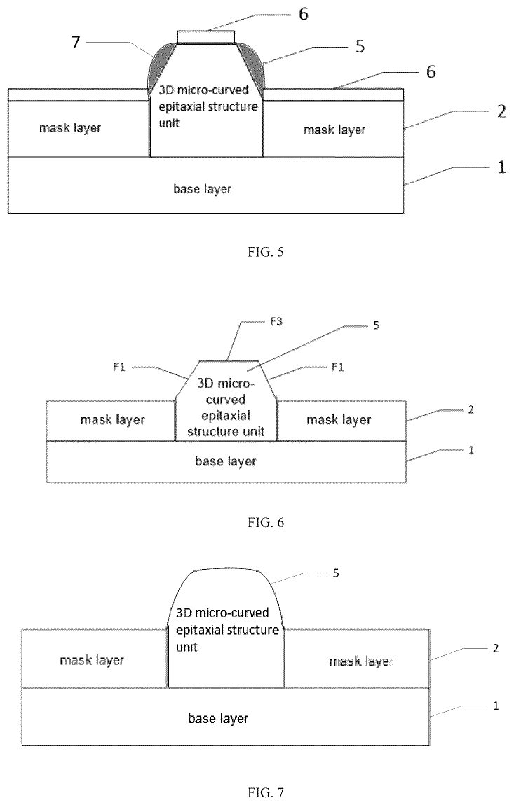

Referring to FIG. 6, wet etching is utilized to etch the region 7, resulting in a structure comprising one polar (0001) F3 plane and two semi-polar (1101) F1 planes. The surface of the ScGaN/ScAlGaN alloy layer readily forms an impermeable passivation layer in strong acid, thus preventing reaction with a 1:1 mixture of nitric acid (HNO₃) and hydrofluoric acid (HF), and it is an excellent etch-stopping etch-layer material for epitaxial critical wet etching in vertical structures. By leveraging the isotropic etching characteristics of wet etching, the molar molecular weight ratio of the Sc source component is set at 5% to 30%. This Sc source component adjusts the crystal orientation angle of the crystal face during wet etching, that is, the angle between the crystal face and the horizontal direction, ultimately resulting in the structure depicted in FIG. 6.

Referring to FIG. 7, put the 3D micro-curved epitaxial structure into the MOCVD reactor again, and under the same growth conditions as used in FIG. 4, an ScGaN or ScAlGaN alloy epitaxial layer is grown on the outer surface of the 3D micro-curved epitaxial structure unit 5.

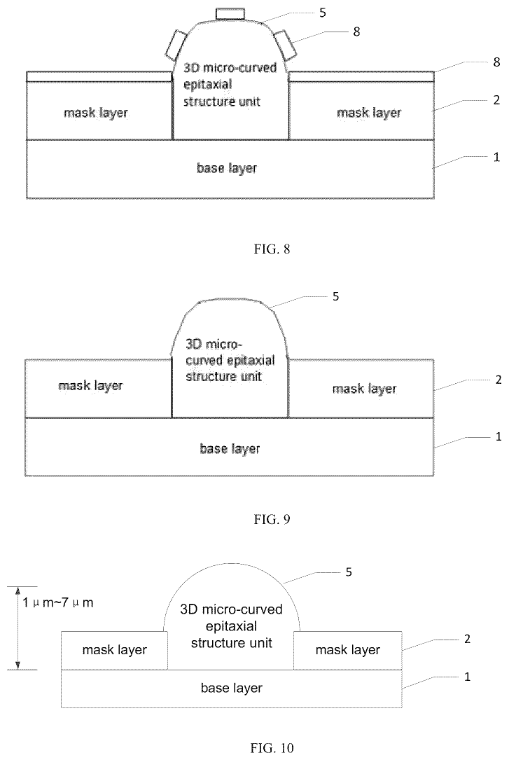

Referring to FIG. 8, the 3D micro-curved epitaxial structure of FIG. 7 is coated with a third photoresist layer 8, exposed, and developed.

Referring to FIG. 9, the 3D micro-curved epitaxial functional structure depicted in FIG. 8 is subjected to wet etching, resulting in the formation of three sets of structures, each comprising one polar plane F3 and two semi-polar planes F1. That is, following MOCVD epitaxial growth and subsequent etching, the original polar plane F3 is transformed into a new configuration comprising one polar plane F3 and two semi-polar planes F1. Similarly, the original semi-polar plane F1, following MOCVD epitaxial growth and etching, forms a new structure with two semi-polar planes F1 and one polar plane F3. The number of polar and semi-polar planes changes according to the rule of 3×3ⁿ (n≥0, n is a natural number).

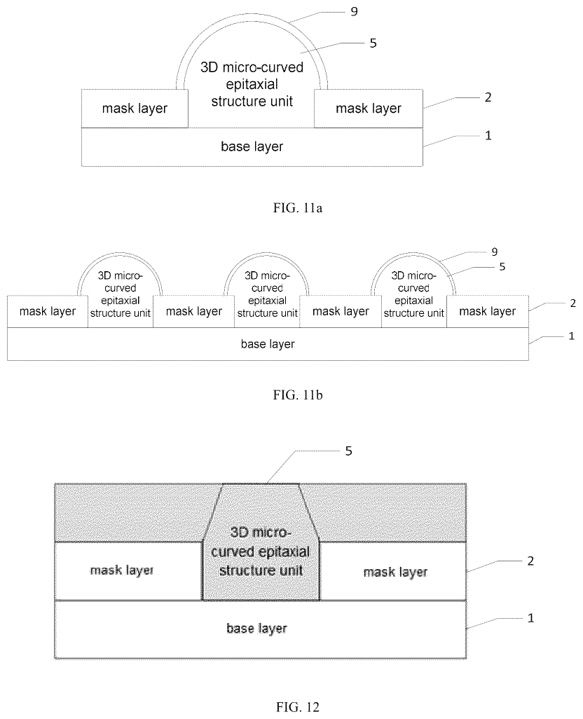

Repeat the steps of MOCVD epitaxy and wet etching of the 3D micro-curved epitaxial functional structure. The upper surface of the 3D micro-curved epitaxial structural unit 5 gradually becomes smooth. Repeat 3 to 10 times until the upper surface is smooth. The height of the 3D micro-curved epitaxial structural unit 5 in the vertical direction from the bottom of the groove 4 to the top of its upper surface is 1 μm to 7 μm, referring to FIG. 10.

Referring to FIGS. 11a and 11b, other additional functional layers 9 are grown on the upper surface of the 3D micro-curved epitaxial structural unit 5. For example, the additional functional layers 9 and the 3D micro-curved epitaxial structural unit 5 together form a heterojunction superlattice multi-quantum well structure. The light emitted from the quantum wells is vertical everywhere. For normal light emission, the light extraction efficiency can be close to the theoretical value of 100%, greatly improving the light extraction efficiency. For instance, the additional functional layers 9 and the 3D micro-curved epitaxial structural unit 5 jointly form a channel layer structure, etc. This approach realizes the compatibility of chip process with epitaxial process, provides technical feasibility for the realization of complex structures, and broadens the application scope of chip devices.

### Example 1

A base layer 1 is provided, comprising a sapphire substrate 11 and a first epitaxial layer 12. A mask layer 2 is grown over the base layer 1, wherein the material of the mask layer 2 is AIN. The mask layer 2 is grown using a CVD process, which involves placing the base layer 1 into a CVD reaction chamber, where the reaction temperature is set at 75° C., with a gas pressure ranging from 1 to 10 torr. A gas flow ratio of aluminum trichloride (AlCl₃) to NH₃ of 1:10 to 1:30 is used. Through a chemical reaction between AlCl₃ and NH₃, an AlN film is generated and deposited on the surface of the first epitaxial layer 12. The thickness of the mask layer is 20 nm.

Coat a first photoresist layer 3 on the mask layer 2, irradiate the first photoresist layer 3 with ultraviolet light or a laser, and then use a developer to remove the exposed first photoresist layer 3, forming a pattern of the area to be etched on the surface of the mask layer 2. Perform ICP dry etching on the mask layer 2, put the sample (the 3D micro-curvature epitaxial functional structure at each growth stage is collectively referred to as the sample) into the ICP etching machine, introduce the combined gases SF₆, O₂ and Ar in a vacuum environment, with the reaction chamber pressure ranging from 10 to 50 mTorr, forming uniformly distributed grooves 4 that penetrate the mask layer 2 and have their bottoms on the upper surface of the base layer 1.

Grow the 3D micro-curved epitaxial structural unit 5 by placing the sample into the MOCVD reactor and introducing H₂, NH₃, N₂, Sc source, and excess Ga source in an environment of 400 to 900° C. Here, the Ga source flow rate is 10,000 sccm, while the H₂, NH₃, N₂ flow rates are all 50 L/min. The 3D micro-curved epitaxial structural unit 5 is grown using ScGaN alloy. The Ga source flow rate is approximately 10 times that of the traditional growth method. The excess Ga source serves as a surfactant or surface lubricant, regulating the growth rate of the semi-polar surface and enabling selective growth of ScGaN thin films, thus providing conditions for the surface growth of the 3D micro-curvature epitaxial structure units 5. The reaction temperature in the MOCVD reactor ranges from 400 to 900° C., instead of the traditional high temperature above 1000° C., enabling repeated epitaxial growth of the ScGaN alloy layer of the 3D micro-curved epitaxial structure units 5.

The sample is coated with the second photoresist layer 6, exposed, and developed to determine the area 7 to be etched. The region 7 to be etched is then wet etched, forming a structure that includes one polar plane (0001) F3 and two semi-polar planes (1101) F1. The surface of the ScGaN alloy layer readily forms an impermeable passivation layer in strong acid, thus preventing reaction with a 1:1 mixture of nitric acid (HNO₃) and hydrofluoric acid (HF), and it is an excellent self-stopping etch-layer material for epitaxial critical wet etching in vertical structures. By leveraging the isotropic etching characteristics of wet etching, the molar molecular weight ratio of the Sc source component is set at 5% to 30%. This Sc source component adjusts the crystal orientation angle of the crystal face during wet etching, that is, the angle between the crystal face and the horizontal direction.

The sample is put into the MOCVD reactor again, and the same growth conditions are used as in the previous steps of this embodiment, and a ScGaN alloy layer is epitaxially grown on the outer surface of the 3D micro-curvature epitaxial structural unit 5.

The sample is coated with the third photoresist layer 8, subsequently exposed, and developed. Following this, the sample undergoes a second wet etching process. After the etching, the 3D micro-curved epitaxial structural unit 5 is transformed into a configuration comprising three sets of structures, each comprising one polar plane F3 and two semi-polar planes F1. The original polar plane F3, upon MOCVD epitaxial growth and subsequent etching, is restructured into a new configuration with one polar plane F3 and two semi-polar planes F1. Similarly, the original semi-polar plane F1, following MOCVD epitaxial growth and etching, forms a new structure with two semi-polar planes F1 and one polar plane F3.

Repeatedly perform the steps of MOCVD epitaxial growth and wet etching on the sample. Through this process, the upper surface of the 3D micro-curved epitaxial structural unit 5 gradually achieves smoothness. After repeating the steps eight times, the upper surface of the 3D micro-curved epitaxial structural unit 5 becomes smooth, with the excess Ga source simultaneously rectifying the curvature of the microstructure surface, resulting in a smoother curvature.

Additional functional layers are grown on the upper surface of the 3D micro-curved epitaxial structural unit 5. Specifically, an InGaN (indium gallium nitrogen) layer is grown in conjunction with the 3D micro-curved epitaxial structural unit 5, forming a heterojunction superlattice multi-quantum well structure. The light emitted from the quantum wells is vertical everywhere. For normal light emission, the light extraction efficiency can be close to the theoretical value of 100%, greatly improving the light extraction efficiency. Notably, the curvature of the 3D micro-curved epitaxial structural unit 5 ranges from 1000R to 1800R, fully satisfying the curvature design requirements of existing curved screens in the market.

### Example 2

A base layer 1 is provided, comprising a sapphire substrate 11 and a first epitaxial layer 12. A mask layer 2 is grown over the base layer 1, wherein the material of the mask layer 2 is SiN. The mask layer 2 is grown using a PVD process, which involves placing the base layer 1 into a PVD reaction chamber and introducing a silicon source and NH₃ gas. During the process, the substrate heating temperature is maintained at no higher than 400° C., enabling a chemical reaction between the silicon source and NH₃ to generate a SiN film. The SiN film is then deposited onto the surface of the first epitaxial layer 12, the mask layer has a thickness of 100 nm.

Coat a first photoresist layer 3 on the mask layer 2, irradiate the first photoresist layer 3 with ultraviolet light or a laser, and then use a developer to remove the exposed first photoresist layer 3, forming a pattern of the area to be etched on the surface of the mask layer 2. Perform ICP dry etching on the mask layer 2, put the sample (the 3D micro-curvature epitaxial functional structure at each growth stage is collectively referred to as the sample) into the ICP etching machine, introduce the combined gases SF₆, O₂ and Ar in a vacuum environment, with the reaction chamber pressure ranging from 10 to 50 mTorr, forming uniformly distributed grooves 4 that penetrate the mask layer 2 and have their bottoms on the upper surface of the base layer 1.

Grow the 3D micro-curvature epitaxial structure units 5 by placing the sample into the MOCVD reactor and introducing H₂, NH₃, N₂, Sc source, Al source, and excess Ga source in an environment of 400 to 900° C. The Ga source flow rate is approximately 50 times higher than in traditional growth methods, with 50000 sccm, while the Al source flow rate is 500 sccm. The H₂ flow rate is 75 L/min, the NH₃ flow rate is 75 L/min, and the N₂ flow rate is 100 L/min, and the 3D micro-curved epitaxial structural unit 5 made of ScAlGaN alloy material is grown. The excess Ga source serves as a surfactant or surface lubricant, controlling the growth rate of the semi-polar surface and enabling selective growth of ScAlGaN thin films, thus providing conditions for the surface growth of the 3D micro-curvature epitaxial structure units 5. The reaction temperature in the MOCVD container ranges from 400 to 900° C., instead of the traditional high temperature above 1000° C., enabling repeated epitaxial growth of the ScAlGaN alloy layer of the 3D micro-curved epitaxial structure units 5.

The sample is coated with the second photoresist layer 6, exposed, and developed to determine the area 7 to be etched. The region 7 to be etched is then wet etched, forming a structure that includes one polar plane (0001) F3 and two semi-polar planes (1101) Fl. The surface of the ScAlGaN alloy layer readily forms an impermeable passivation layer in strong acid, thus preventing reaction with a 1:1 mixture of nitric acid (HNO₃) and hydrofluoric acid (HF), and it is an excellent self-stopping etch-layer material for epitaxial critical wet etching in vertical structures. By leveraging the isotropic etching characteristics of wet etching, the molar molecular weight ratio of the Sc source component is set at 5% to 30%. This Sc source component adjusts the crystal orientation angle of the crystal face during wet etching, that is, the angle between the crystal face and the horizontal direction.

The sample is placed into the MOCVD reactor again, and the same growth conditions are used as in the previous steps of this embodiment, and a ScAlGaN alloy layer is epitaxially grown on the outer surface of the 3D micro-curvature epitaxial structural unit 5.

The sample is coated with the third photoresist layer 8, subsequently exposed, and developed. Following this, the sample undergoes a second wet etching process. After the etching, the 3D micro-curved epitaxial structural unit 5 is transformed into a configuration comprising three sets of structures, each consisting of one polar plane F3 and two semi-polar planes F1. The original polar plane F3, upon MOCVD epitaxial growth and subsequent etching, is restructured into a new configuration with one polar plane F3 and two semi-polar planes F1. Similarly, the original semi-polar plane F1, following MOCVD epitaxial growth and etching, forms a new structure with two semi-polar planes F1 and one polar plane F3.

Repeatedly perform the steps of MOCVD epitaxial growth and wet etching on the sample. Through this process, the upper surface of the 3D micro-curved epitaxial structural unit 5 gradually achieves smoothness. After repeating the steps five times, the upper surface of the 3D micro-curved epitaxial structural unit 5 becomes smooth, with the excess Ga source simultaneously rectifying the curvature of the microstructure surface, resulting in a smoother curvature.

Additional functional layers are grown on the upper surface of the 3D micro-curved epitaxial structural unit 5. Specifically, an indium gallium nitrogen (InGaN) layer is grown in conjunction with the 3D micro-curved epitaxial structural unit 5, forming a heterojunction superlattice multi-quantum well structure. The light emitted from the quantum wells is vertical everywhere. For normal light emission, the light extraction efficiency can be close to the theoretical value of 100%, greatly improving the light extraction efficiency. Notably, the curvature of the 3D micro-curved epitaxial structural unit 5 ranges from 1000R to 1800R, fully satisfying the curvature design requirements of existing curved screens in the market.

### Example 3

A base layer 1 is provided, comprising a sapphire substrate 11 and a first epitaxial layer 12. A mask layer 2 is grown over the base layer 1, wherein the material of the mask layer 2 is AIN. The mask layer 2 is grown using a CVD process, which involves placing the base layer 1 into a CVD reaction chamber, where the reaction temperature is set at 75° C., with a gas pressure ranging from 1 to 10 torr. A gas flow ratio of aluminum trichloride (AlCl₃) to NH₃ of 1:10 to 1:30 is used. Through a chemical reaction between AlCl₃ and NH₃, an AIN film is generated and deposited on the surface of the first epitaxial layer 12. The thickness of the mask layer is 500 nm.

Coat a first photoresist layer 3 on the mask layer 2, irradiate the first photoresist layer 3 with ultraviolet light or a laser, and then use a developer to remove the exposed first photoresist layer 3, forming a pattern of the area to be etched on the surface of the mask layer 2. Perform ICP dry etching on the mask layer 2, place the sample (the 3D micro-curvature epitaxial functional structure at each growth stage is collectively referred to as the sample) into the ICP etching machine, introduce the combined gases SF₆, O₂ and Ar in a vacuum environment, with the reaction chamber pressure ranging from 10 to 50 mTorr, forming uniformly distributed grooves 4 that penetrate the mask layer 2 and have their bottoms on the upper surface of the base layer 1.

Grow the 3D micro-curved epitaxial structural unit 5 by placing the sample into the MOCVD reactor and introducing H₂, NH₃, N₂, Sc source, and excess Ga source in an environment of 400 to 900° C. Here, the Ga source flow rate is 100,000 sccm, while the H₂ flow rate is 100 L/min, the NH₃ flow rate is 100 L/min, the N₂ flow rate is 150 L/min. The 3D micro-curved epitaxial structural unit 5 is grown using ScGaN alloy. The Ga source flow rate is approximately 100 times that of the traditional growth method. The excess Ga source serves as a surfactant or surface lubricant, regulating the growth rate of the semi-polar surface and enabling selective growth of ScGaN thin films, thus providing conditions for the surface growth of the 3D micro-curvature epitaxial structure units 5. The reaction temperature in the MOCVD reactor ranges from 400 to 900° C., instead of the traditional high temperature above 1000° C., enabling repeated epitaxial growth of the ScGaN alloy layer of the 3D micro-curved epitaxial structure units 5.

The sample is coated with the second photoresist layer 6, exposed, and developed to determine the area 7 to be etched. The region 7 to be etched is then wet etched, forming a structure that includes one polar plane (0001) F3 and two semi-polar planes (1101) F1. The surface of the ScGaN alloy layer readily forms an impermeable passivation layer in strong acid, thus preventing reaction with a 1:1 mixture of nitric acid (HNO₃) and hydrofluoric acid (HF), and it is an excellent self-stopping etch-layer material for epitaxial critical wet etching in vertical structures. By leveraging the isotropic etching characteristics of wet etching, the molar molecular weight ratio of the Sc source component is set at 5% to 30%. This Sc source component adjusts the crystal orientation angle of the crystal face during wet etching, that is, the angle between the crystal face and the horizontal direction.

The sample is placed into the MOCVD reactor again, and the same growth conditions as in the previous steps of this embodiment are applied. A ScGaN alloy layer is epitaxially grown on the outer surface of the 3D micro-curvature epitaxial structural unit 5.

The sample is coated with the third photoresist layer 8, subsequently exposed, and developed. Following this, the sample undergoes a second wet etching process. After the etching, the 3D micro-curved epitaxial structural unit 5 is transformed into a configuration comprising three sets of structures, each consisting of one polar plane F3 and two semi-polar planes F1. The original polar plane F3, upon MOCVD epitaxial growth and subsequent etching, is restructured into a new configuration with one polar plane F3 and two semi-polar planes F1. Similarly, the original semi-polar plane F1, following MOCVD epitaxial growth and etching, forms a new structure with two semi-polar planes F1 and one polar plan F3.

Repeatedly perform the steps of MOCVD epitaxial growth and wet etching on the sample. Through this process, the upper surface of the 3D micro-curved epitaxial structural unit 5 gradually achieves smoothness. After repeating the steps three times, the upper surface of the 3D micro-curved epitaxial structural unit 5 becomes smooth, with the excess Ga source simultaneously rectifying the curvature of the microstructure surface, resulting in a smoother curvature.

Additional functional layers are grown on the upper surface of the 3D micro-curved epitaxial structural unit 5. Specifically, an indium gallium nitrogen (InGaN) layer is grown in conjunction with the 3D micro-curved epitaxial structural unit 5, forming a heterojunction superlattice multi-quantum well structure. The light emitted from the quantum wells is vertical everywhere. For normal light emission, the light extraction efficiency can be close to the theoretical value of 100%, greatly improving the light extraction efficiency. Notably, the curvature of the 3D micro-curved epitaxial structural unit 5 ranges from 1000R to 1800R, fully satisfying the curvature design requirements of existing curved screens in the market.

### Comparative Example 1

The difference from Example 3 is that, when the sample is introduced into the MOCVD reactor for the reaction process, a normal amount of Ga source is used, which is less than 1000 sccm. It cannot serve as a surfactant or surface lubricant, nor can it effectively regulate the growth rate of the semi-polar surface. Consequently, the selective growth of ScGaN films cannot be achieved. During the subsequent epitaxial growth, the film will simultaneously cover the mask layer 2 and the 3D micro-curved epitaxial structural unit 5, as illustrated in FIG. 12. After multiple epitaxial growth and etching steps, a 3D micro-curved epitaxial functional structure cannot be achieved.

### Comparative Example 2

The difference from Example 3 is that, during the reaction process when the sample is placed in the MOCVD reactor, the absence of Sc source gas prohibits the growth of the ScGaN film. Additionally, during the wet etching process, the crystal orientation angle of the crystal surface cannot be effectively controlled. This limitation renders the achievement of a 3D micro-curved epitaxial functional structure impossible after three repeated epitaxial growth cycles, thereby preventing the subsequent growth of additional functional layers.

The above description is only a description of the preferred embodiments of the present invention, and does not limit the scope of the present invention in any way. Any changes or modifications made by those of ordinary skill in the field of the present invention based on the above disclosure shall fall within the scope of the claims.

What is claimed:

1. A method for preparing a three-dimensional (3D) micro-curved epitaxial functional structure, comprising:
step S1 of providing a base layer, which comprises at least a sapphire substrate layer and a first epitaxial layer in order from bottom to top;
step S2 of growing a mask layer above the base layer;
step S3 of dry etching the mask layer to form spaced grooves, wherein the grooves penetrate through the mask layer and have their bottoms positioned on the upper surface of the base layer, to obtain a sample;
step S4 of placing the sample into a reactor, and introducing hydrogen (H₂), ammonia (NH₃), nitrogen (N₂), a scandium (Sc) source, and an excess Ga source under a temperature range of 400° C. to 900° C. to grow 3D micro-curved epitaxial structural units;
step S5 of performing photolithography on the 3D micro-curved epitaxial structural units to define an area to be etched;
step S6 of wet etching the area to be etched to form a structure comprising one polar plane F3 and two semi-polar planes F1;
step S7 of repeating steps S4 to S6;
wherein a Ga source flow rate is 10,000 sccm to 100,000 sccm, an H₂ flow rate is 50 L/min to 100 L/min, an NH₃ flow rate is 50 L/min to 100 L/min, and a N₂ flow rate is 50 L/min to 150 L/min; and
a curvature of the 3D micro-curved epitaxial structural units is 1000R to 1800R.

2. The method according to claim 1, further comprising: introducing an aluminum (Al) source, wherein a flow rate of the Al source is 50 sccm to 1000 sccm, and a molar molecular weight ratio of the Al source is 5% to 90%.

3. The method according to claim 1, wherein the step S7 is repeated 3 to 10 times.

4. The method according to claim 3, further comprising: growing an additional functional layer on the outer surface of the 3D micro-curved epitaxial structural unit, wherein the additional functional layer and the 3D micro-curved epitaxial structural unit form a heterojunction superlattice multi-quantum well structure layer or a channel layer.

5. The method according to claim 1, wherein a molar molecular weight ratio of the Sc source is 5% to 30%.

6. A three-dimensional (3D) micro-curved epitaxial functional structure, comprising:
a base layer, which includes at least a sapphire substrate layer and a first epitaxial layer, arranged sequentially from bottom to top;
a mask layer located above the base layer;
the mask layer provided with grooves distributed at intervals, wherein the grooves penetrate the mask layer and expose the upper surface of the base layer;
a plurality of 3D micro-curved epitaxial structural units, wherein a bottom part of each of the plurality of 3D micro-curved epitaxial structural units is filled with the corresponding groove, and an upper surface is a smooth 3D micro-curved structure, and each of the plurality of 3D micro-curved epitaxial structural units is in contact with the upper surface of the mask layer.

7. The 3D micro-curved epitaxial functional structure according to claim 6, wherein the mask layer is AlN or SiN, and each of the plurality of the 3D micro-curved epitaxial structural units is made of ScGaN or ScAlGaN and its superlattice structure.

8. The 3D micro-curved epitaxial functional structure according to claim 6, further comprising an additional functional layer that covers each of the plurality of the 3D micro-curved epitaxial structural units and forms a heterojunction superlattice multi-quantum well structure or channel layer with the each of the plurality of 3D micro-curved epitaxial structural units.

9. The 3D micro-curved epitaxial functional structure according to claim 6, wherein the vertical height of each of the plurality of the 3D micro-curved epitaxial structural units from the bottom of the groove to the top of the upper surface is 1 μm to 7 μm.

10. The method according to claim 1, wherein after Metal-organic Chemical Vapor Deposition (MOCVD) epitaxial growth in the reactor and subsequent etching, an original polar plane F3 is transformed into a new structure comprising one polar plane F3 and two semi-polar planes F1, and similarly, an original semi-polar plane F1 is also transformed, after MOCVD epitaxial growth and etching, into a new structure comprising two semi-polar planes F1 and one polar plane F3, until a smooth upper surface of the 3D micro-curved epitaxial structural units is achieved, thereby obtaining the 3D micro-curved epitaxial functional structure.
